(19) United States
(12) Patent Application Publication
(10) Pub. No.: US 2026/0082638 A1
(43) Pub. Date: Mar. 19, 2026

(54) Semiconductor Devices and Methods of Manufacturing Semiconductor Device

(71) Applicant: Episil Technologies Inc., Hsinchu County (TW)

(72) Inventors: Yuan Liang LIU, Shinchu County (TW); Yen Chang CHEN, Shinchu County (TW); Yuan Chou CHANG, Shinchu County (TW); Yi Chen LEE, Shinchu County (TW)

(21) Appl. No.: 19/198,244

(22) Filed: May 5, 2025

(30) Foreign Application Priority Data
Sep. 19, 2024 (TW) 113135414

(51) Int. Cl. H10D 30/83; H10D 30/01; H10D 62/832

(52) U.S. Cl. CPC H10D 30/831; H10D 30/0515; H10D 62/8325

(57) ABSTRACT

Embodiments of the present disclosure illustrate a semiconductor device. The semiconductor device comprises a silicon carbide epitaxial layer, comprising: a p-type well region; a junction field effect region adjacent to the p-type well region; a heavily doped n-type region on a surface of the p-type well region; and a heavily doped p-type region below the heavily doped n-type region and within the p-type well region. The semiconductor device further comprises an island-shaped oxide layer on the junction field effect region; a gate oxide layer covering the p-type well region, the junction field effect region, the heavily doped n-type region, the heavily doped p-type region and the island-shaped oxide; and a polycrystalline silicon layer on the gate oxide layer without contacting the island-shaped oxide.

### BACKGROUND OF THE INVENTION

### Field of the Invention

The present invention relates to a semiconductor device, in particular relates to a power metal oxide semiconductor transistor.

### Description of the Related Art

In conventional power metal oxide semiconductor transistors, the gate-to-drain capacitance (Cgd) affects the switching energy loss of the device. However, it is currently difficult to effectively control the oxide thickness between the gate and the drain independently to reduce the gate-to-drain capacitance. Thus, there is a need for a new semiconductor device and a new method for manufacturing a semiconductor device to overcome the said problems.

### BRIEF SUMMARY OF THE INVENTION

In light of the previously described problems, the present disclosure provides a semiconductor device, comprising a silicon carbide epitaxial layer, comprising: a p-type well region; a junction field effect region adjacent to the p-type well region; a heavily doped n-type region on a surface of the p-type well region; and a heavily doped p-type region below the heavily doped n-type region and within the p-type well region. The semiconductor device further comprises: an island-shaped oxide on the junction field effect region; a gate oxide layer covering the p-type well region, the junction field effect region, the heavily doped n-type region, the heavily doped p-type region and the island-shaped oxide; and a polycrystalline silicon layer on the gate oxide layer without contacting the island-shaped oxide.

The present disclosure also provides a method of manufacturing a semiconductor device comprising: providing a silicon carbide epitaxial layer, wherein a p-type well region, a heavily doped n-type region on a surface of the p-type well region, a heavily doped p-type region below the heavily doped n-type region and within the p-type well region, and a junction field effect region adjacent to the p-type well region are predefined in the silicon carbide epitaxial layer; depositing an oxide layer; applying a patterning process to the oxide layer to form an island-shaped oxide, wherein the island-shaped oxide is on the junction field effect region; depositing a gate oxide layer to cover the p-type well region, the junction field effect region, the heavily doped n-type region, the heavily doped p-type region and the island-shaped oxide; and depositing a polycrystalline silicon layer on the gate oxide layer.

In summary, when the width of the junction field-effect region is reduced to decrease the overall cell pitch and thereby lower the drain-to-source on-resistance (Rdson), the gate-to-drain capacitance may be maintained at a low level by forming the island-shaped oxide and depositing the gate oxide layer to preserve the spacing between the polycrystalline silicon layer and the junction field effect region. Furthermore, the gate-to-drain capacitance may be further reduced by increasing such spacing through the same structural features, thereby improving switching energy loss.

### BRIEF DESCRIPTION OF THE DRAWINGS

FIGS. 1 to 5 are cross-sectional views of a semiconductor device of the present disclosure at various stages, in accordance with some embodiments of the present application.

FIG. 6 is a flow chart of a method for manufacturing a semiconductor device of the present disclosure, in accordance with some embodiments of the present application.

FIGS. 7 to 11 are cross-sectional views of a semiconductor device of the present disclosure at various stages, in accordance with some embodiments of the present application.

FIG. 12 is a flow chart of a method for manufacturing a semiconductor device of the present disclosure, in accordance with some embodiments of the present application.

### DETAILED DESCRIPTION OF THE INVENTION

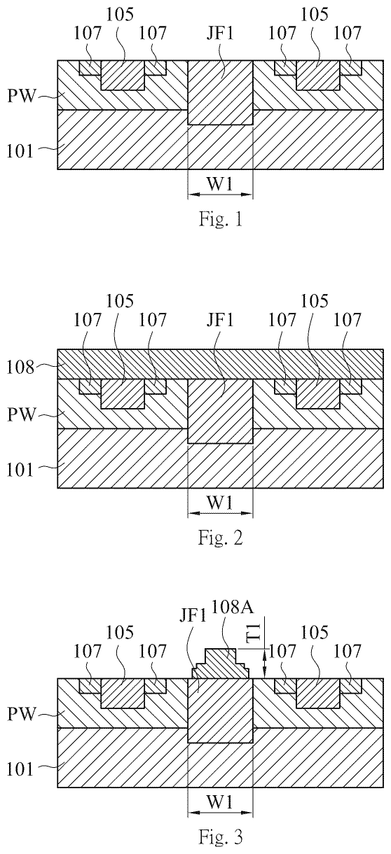

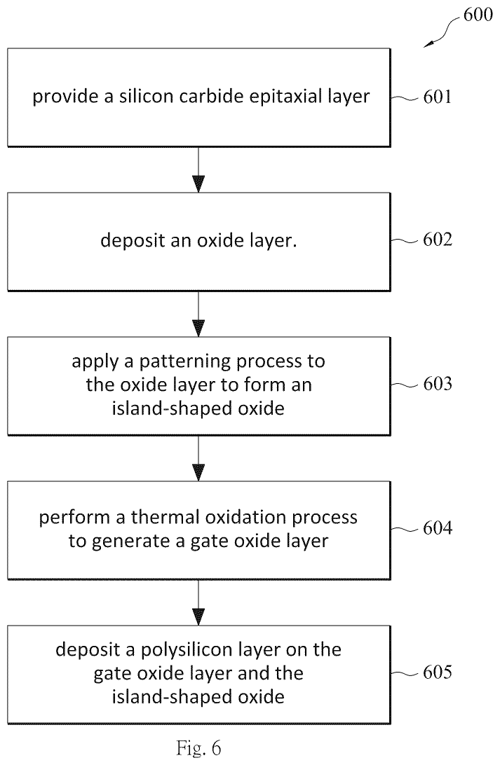

FIGS. 1 to 5 are cross-sectional views of a semiconductor device of the present disclosure at various stages, according to method 600 shown in FIG. 6. In step 601, a silicon carbide epitaxial layer 101 is provided, wherein a p-type well region PW, a heavily doped n-type region 107 on the surface of the p-type well region PW, a heavily doped p-type region 105 below the heavily doped n-type region 107 and within the p-type well region PW, and a junction field region JF1 between two adjacent p-type well regions PW and adjacent to the p-type well region PW are predefined in the silicon carbide epitaxial layer 101, as shown in FIG. 1. The width W1 of the junction field region JF1 may be 1.2 μm. In step 602, an oxide layer 108 is deposited, as shown in FIG. 2. In step 603, a patterning process is applied to the oxide layer 108 to form an island-shaped oxide 108A, as shown in FIG. 3. The patterning process may include a lithography process and an etching process. In some embodiments, the etching process may include a wet etching process and a photoresist removal process. The island-shaped oxide 108A is on the junction field region JF1, and the thickness T1 of the island-shaped oxide 108A may be about 900 Å, while the width of the island-shaped oxide 108A is smaller than the width W1 of the junction field region JF1.

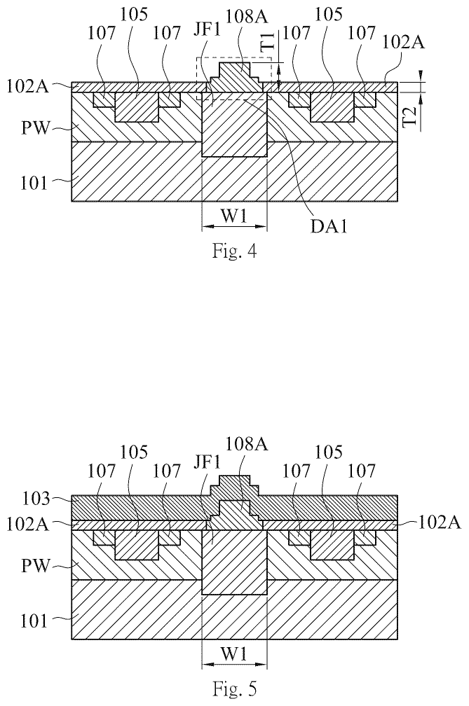

In step 604, a thermal oxidation process is performed to produce a gate oxide layer 102A. As shown in FIG. 4, the gate oxide layer 102A is on and in contact with the p-type well region PW, the heavily doped n-type region 107, the heavily doped p-type region 105, and the junction field region JF1. The gate oxide layer 102A is in contact with only a portion of the side edges of the island-shaped oxide 108A and does not cover the upper surface of the island-shaped oxide 108A. The thickness T2 of the gate oxide layer 102A may be approximately 400 Å, while the thickness of the oxide in the area DA1 over the drain is still approximately 900 Å. In step 605, a polycrystalline silicon layer 103 is deposited on the gate oxide layer 102A and the island-shaped oxide 108A. As shown in FIG. 5, the polycrystalline silicon layer 103 is on the gate oxide layer 102A and the island-shaped oxide 108A and is in contact with the gate oxide layer 102A and the island-shaped oxide 108A. The polycrystalline silicon layer 103 may be formed into a gate of a transistor after being patterned. In addition, regarding the source terminal and the gate terminal, a first metal layer (not shown) is also formed, which may be patterned to form a source contact and a gate contact. The source contact contacts the heavily doped p-type region 105 and the heavily doped n-type region 107 through the metal silicide, and the gate contact may contact the polycrystalline silicon layer 103. Regarding the drain terminal, a silicon carbide substrate (not shown) may be formed under the silicon carbide epitaxial layer 101, and a second metal layer (not shown) may be formed under the silicon carbide substrate as a drain contact.

In a silicon carbide planar metal oxide field effect transistor (SiC planar MOSFET), gate-to-drain capacitance (Cgd) affects the switching energy loss of the device. The gate-to-drain capacitance of the metal oxide field effect transistor shown in FIG. 5 depends on the thickness of the gate oxide (e.g., island-shaped oxide 108A). The thicker the gate oxide, the lower the gate-to-drain capacitance. Lower gate-to-drain capacitance may improve the switching energy loss of the device. The thickness T1 of the island-shaped oxide 108A in FIG. 5 is approximately 900 Å, which produces lower gate-to-drain capacitance. In order to reduce the drain-to-source on-resistance (Rdson), the cell pitch may be reduced. Usually, the method of reducing the cell pitch includes reducing the width W1 of the junction field region JF1. Although the metal oxide field effect transistor under the architecture of FIG. 5 may achieve a reduced gate-to-drain capacitance, if the junction field effect region JF1 is scaled down, the formation of the island-shaped oxide 108A having a width smaller than that of the junction field-effect region JF1 may cause peeling of the photoresist layer disposed on the oxide layer 108. In addition, it may be difficult to increase the thickness of the oxide layer at the oxide (e.g., the island-shaped oxide 108A) of the drain terminal by means of a thermal oxidation process. Therefore, it is relatively difficult to maintain a low gate-to-drain capacitance or to further reduce the gate-to-drain capacitance while reducing the drain-to-source on-resistance (Rdson).

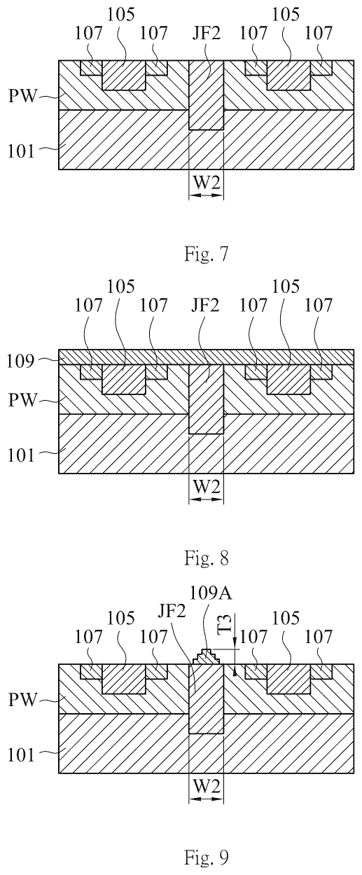

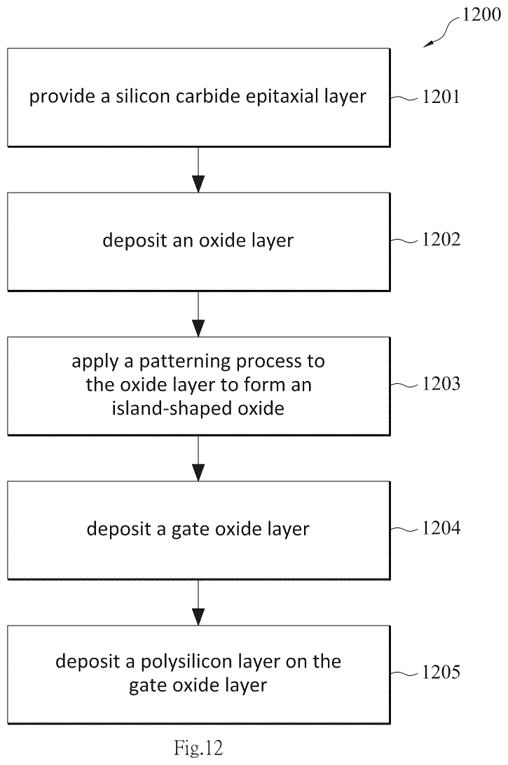

FIGS. 7 to 11 are cross-sectional views of the semiconductor device of the present disclosure at various stages according to method 1200 shown in FIG. 12. FIG. 7 is similar to FIG. 1, and in step 1201, a silicon carbide epitaxial layer 101 is provided, wherein a p-type well region PW, a heavily doped n-type region 107 on the surface of the p-type well region PW, a heavily doped p-type region 105 below the heavily doped n-type region 107 and within the p-type well region PW, and a junction field region JF1 between two adjacent p-type well regions PW and adjacent to the p-type well region PW are predefined in the silicon carbide epitaxial layer 101, wherein the difference between the junction field-effect region JF2 and the junction field-effect region JF1 lies in that the junction field-effect region JF2 is narrower than the junction field-effect region JF1, and a width W2 of the junction field-effect region JF2 may be scaled down to 0.8 μm. In step 1202, an oxide layer 109 is deposited, as shown in FIG. 8. It should be noted that the thickness of the oxide layer 109 in FIG. 8 is thinner than the oxide layer 108 in FIG. 2. In step 1203, a patterning process is applied to the oxide layer 109 to form an island-shaped oxide 109A, as shown in FIG. 9. The patterning process may include a lithography process and an etching process. In some embodiments, the etching process may include a wet etching process and a photoresist removal process. The island-shaped oxide 109A is on the junction field region JF2, and the thickness T3 of the island-shaped oxide 109A may be about 500 Å, while the width of the island-shaped oxide 109A is smaller than the width W2 of the junction field region JF2.

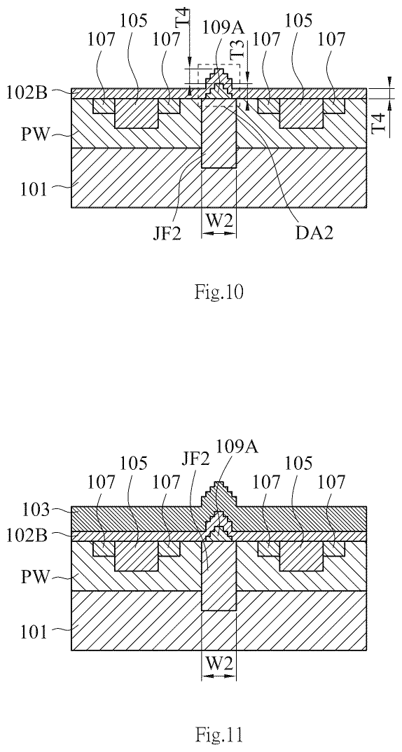

In step 1204, a gate oxide layer 102B is deposited to cover the p-type well region PW, the junction field effect region JF2, the heavily doped n-type region 107, the heavily doped p-type region 105 and the island-shaped oxide 109A. As shown in FIG. 10, the gate oxide layer 102B is on and in contact with the p-type well region PW, the heavily doped n-type region 107, the heavily doped p-type region 105, the junction field effect region JF2, and the island-shaped oxide 109A. The thickness T4 of the gate oxide layer 102B may be about 400 Å. Therefore, the thickness of the oxide in the area DA2 over the drain is 500 Å (the thickness T3 of the island-shaped oxide 109A) plus 400 Å (the thickness T4 of the gate oxide layer 102B), resulting in a total thickness of 900 Å. In step 1205, a polycrystalline silicon layer 103 is deposited on the gate oxide layer 102B. As shown in FIG. 11, the polycrystalline silicon layer 103 is on and in contact with the gate oxide layer 102B, but is not in contact with the island-shaped oxide 109A. The polycrystalline silicon layer 103 may be formed into a gate of a transistor after being patterned. Similarly, regarding the source terminal and the gate terminal, a first metal layer (not shown) is also formed, wherein the first metal layer may be patterned to form a source contact and a gate contact. The source contact contacts the heavily doped p-type region 105 and the heavily doped n-type region 107 through the metal silicide, and the gate contact may contact the polycrystalline silicon layer 103. Regarding the drain terminal, a silicon carbide substrate (not shown) may be formed under the silicon carbide epitaxial layer 101, and a second metal layer (not shown) may be formed under the silicon carbide substrate as a drain contact.

The gate oxide layers in the structure shown in FIG. 11 are all deposited oxide layers, rather than being produced by a thermal oxidation process. Therefore, when the width W2 of the junction field effect region JF2 is reduced and then the oxide (such as the island-shaped oxide 109A) at the drain terminal (e.g., in area DA2) is reduced, the thickness of the oxide at the drain terminal may be compensated by the gate oxide layer 102B. In terms of the ratio of the thickness of the oxide at the drain terminal to the width of the junction field region, in FIG. 5, the ratio of the maximum distance (approximately 900 Å, which is the thickness T1 of the island-shaped oxide 108A) between the polycrystalline silicon layer 103 and the junction field region JF1 to the width W1 (approximately 1.2 μm) of the junction field region JF1 is 0.075. In FIG. 11, the ratio of the maximum distance (approximately 900 Å, which is the thickness T3 of the island-shaped oxide 109A plus the thickness T4 of the gate oxide layer 102B) between the polycrystalline silicon layer 103 and the junction field effect region JF2 to the width W2 (approximately 0.8 μm) of the junction field effect region JF2 is 0.1125, which is greater than 0.075. In some embodiments, the width W2 of the junction field effect region JF2 may be reduced while maintaining the maximum distance (approximately 900 Å) between the polycrystalline silicon layer 103 and the junction field effect region JF2, or the width W2 (approximately 0.8 μm) of the junction field effect region JF2 may be maintained while increasing the maximum distance (approximately 900 Å) between the polycrystalline silicon layer 103 and the junction field effect region JF2. Therefore, the ratio of the maximum distance to the width W2 of the junction field effect region JF2 may be larger than 0.1125, for example, even greater than 0.2 or 0.3, etc. In summary, the architecture of FIG. 11 may maintain low gate-to-drain capacitance or reduce gate-to-drain capacitance (increase the maximum distance between the polycrystalline silicon layer 103 and the junction field effect region JF2) when reducing the width of the junction field effect region to decrease the overall cell pitch and thereby lower the drain-to-source on-resistance (Rdson), thereby further improving switching energy loss.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor device comprising:
a silicon carbide epitaxial layer comprising:
a p-type well region;
a junction field effect region adjacent to the p-type well region;
a heavily doped n-type region on a surface of the p-type well region; and
a heavily doped p-type region below the heavily doped n-type region and within the p-type well region;
an island-shaped oxide on the junction field effect region;
a gate oxide layer covering the p-type well region, the junction field effect region, the heavily doped n-type region, the heavily doped p-type region and the island-shaped oxide; and
a polycrystalline silicon layer on the gate oxide layer without contacting the island-shaped oxide.

2. The semiconductor device of claim 1, wherein a width of the island-shaped oxide is smaller than a width of the junction field effect region.

3. The semiconductor device of claim 1, wherein a ration of a maximum distance of the polycrystalline silicon layer and the junction field effect region to a width of the junction field effect region is greater than 0.075.

4. The semiconductor device of claim 1, further comprising:
a first metal layer in contact with the heavily doped p-type region and the heavily doped n-type region through a metal silicide.

5. The semiconductor device of claim 1, further comprising:
a silicon carbide substrate under the silicon carbide epitaxial layer; and
a second metal layer under the silicon carbide substrate.

6. A method for manufacturing a semiconductor device, comprising:
providing a silicon carbide epitaxial layer, wherein a p-type well region, a heavily doped n-type region on a surface of the p-type well region, a heavily doped p-type region below the heavily doped n-type region and within the p-type well region, and a junction field effect region adjacent to the p-type well region are predefined in the silicon carbide epitaxial layer;
depositing an oxide layer;
applying a patterning process to the oxide layer to form an island-shaped oxide, wherein the island-shaped oxide is on the junction field effect region;
depositing a gate oxide layer to cover the p-type well region, the junction field effect region, the heavily doped n-type region, the heavily doped p-type region and the island-shaped oxide; and
depositing a polycrystalline silicon layer on the gate oxide layer.

7. The method of claim 6, wherein a width of the island-shaped oxide is smaller than a width of the junction field effect region.

8. The method of claim 6, wherein a ration of a maximum distance of the polycrystalline silicon layer and the junction field effect region to a width of the junction field effect region is greater than 0.075.

9. The method of claim 6, further comprising:
forming a first metal layer; and
patterning the first metal layer to form a source contact and a gate contact.

10. The method of claim 6, further comprising:
forming a silicon carbide substrate under the silicon carbide epitaxial layer; and
forming a second metal layer under the silicon carbide substrate.
